(19) United States
(12) Patent Application Publication
(10) Pub. No.: US 2010/0154867 A1
(43) Pub. Date: Jun. 24, 2010

(54) MECHANICALLY RELIABLE SOLAR CELL MODULES

(75) Inventors: Stephen J. Bennison, Wilmington, DE (US); Kristof Proost, Hemiksem (BE); Richard Allen Hayes, Beaumont, TX (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, Wilmington, DE (US)

(21) Appl. No.: 12/626,088

(22) Filed: Nov. 25, 2009

Related U.S. Application Data
(60) Provisional application No. 61/139,139, filed on Dec. 19, 2008.

(51) Int. Cl. H01L 31/048; B32B 37/00; B29C 65/02

(52) U.S. Cl. 136/251; 156/60; 156/285

(57) ABSTRACT

A thin film solar cell module comprising thin film solar cells deposited on a first float glass sheet, an ionomer encapsulant sheet and a float glass protective sheet.

### CROSS-REFERENCE TO RELATED APPLICATION

This application claims priority to U.S. Provisional Appln. No. 61/139139, filed on Dec. 19, 2008, which is incorporated herein by reference in their entirety.

### FIELD OF THE INVENTION

The present invention is directed to mechanically reliable thin film solar cell modules.

### BACKGROUND OF THE INVENTION

Because they provide a sustainable energy resource, the use of solar cells is rapidly expanding. Solar cells can typically be categorized into two types based on the light absorbing material used, i.e., bulk or wafer-based solar cells and thin film solar cells.

Monocrystalline silicon (c-Si), poly- or multi-crystalline silicon (poly-Si or mc-Si) and ribbon silicon are the materials used most commonly in forming the more traditional wafer-based solar cells. Solar cell modules derived from wafer-based solar cells often comprise a series of self-supporting wafers (or cells) that are soldered together. The wafers generally have a thickness of between about 180 and about 240 μm. Such a panel of solar cells is called a solar cell layer and it may further comprise electrical wirings such as cross ribbons connecting the individual cell units and bus bars having one end connected to the cells and the other exiting the module. The solar cell layer is then further laminated to encapsulant layer(s) and protective layer(s) to form a weather resistant module that may be used for at least 20 years. In general, a solar cell module derived from wafer-based solar cell(s) comprises, in order of position from the front sun-facing side to the back non-sun-facing side: (1) an incident layer (or front sheet), (2) a front encapsulant layer, (3) a solar cell layer, (4) a back encapsulant layer, and (5) a backing layer (or back sheet). In such modules, it is essential that the materials positioned to the sun-facing side of the solar cell layer (i.e., the incident layer and the front encapsulant layer) have good transparency to allow sufficient sun light reaching the solar cells. In addition, some modules may comprise bi-facial solar cells, where the solar cells are able to generate electrical power by receiving sun light directly reaching the sun-facing side thereof and by receiving sun light that are reflected back to the non-sun-facing side thereof. In such modules it is essential that all the materials surrounding the solar cells layer be sufficiently transparent.

The increasingly important alternative thin film solar cells are commonly formed from materials that include amorphous silicon (a-Si), microcrystalline silicon (μc-Si), cadmium telluride (CdTe), copper indium selenide (CuInSe₂ or CIS), copper indium/gallium diselenide (CuInₓGa₍₁₋ₓ₎Se₂ or CIGS), light absorbing dyes, and organic semiconductors. By way of example, thin film solar cells are disclosed in e.g., U.S. Pat. Nos. 5,507,881; 5,512,107; 5,948,176; 5,994,163; 6,040,521; 6,137,048; and 6,258,620 and U.S. Patent Publication Nos. 2007/98590; 2007/0281090; 2007/0240759; 2007/0232057; 2007/0238285; 2007/0227578; 2007/0209699; and 2007/0079866. Thin film solar cells with a typical thickness of less than 2 μm are produced by depositing the semiconductor layers onto a superstrate (which faces to the sun when in use) or substrate (which faces away from the sun when in use). To be incorporated into a module, the thin film solar cells are then laminated to (a) a polymeric (back) encapsulant sheet and a protective back sheet (also referred to as a backing layer, which is used when the solar cells are deposited on a superstrate) or (b) a polymeric (front) encapsulant sheet and a protective front sheet (also referred to as an incident layer, which is used when the solar cells are deposited on a substrate). As the substrates, the superstrates, the front sheets, and the back sheets share some common functions in the solar cell modules, such as providing mechanical support to the module and protecting the solar cells from the environment, they are also referred to as protective sheets or layers. In addition, in order to maximize the power output, some of the protective sheets, i.e., the superstrates and the front sheets, need to be substantially transparent so that sufficient sun light can reach the solar cells. Glass and flexible films (both plastic and metal films) have been used in forming the various protective sheets in such thin film solar cell modules. However, glass remains the most desirable choice due to its mechanical and optical properties.

In such glass/glass type of thin film solar cell modules, the solar cells are first formed by directly depositing the semiconducting material on a glass superstrate or substrate, and then further laminated to a glass protective sheet (i.e., a back or front sheet) over a polymeric encapsulant sheet.

Float glass (also referred to as annealed glass or annealed float glass) is made by floating molten glass on a bath of molten tin and then allowing it to cool slowly, without being quenched. Additionally, the glass is heat treated in an annealing process to minimize residual stresses due to non-uniform cooling and thermal gradients. Such a process gives the float glass sheets uniform thickness and very flat surfaces. Thus, float glass has been a primary choice to be used as the superstrates or substrates wherein the thin film solar cells are deposited thereon. However, such float glass sheets are without surface compressive stresses caused by further heat or chemical treatment and therefore prone to breakage. In practice, to obtain mechanically reliable thin film solar cell modules, the back or front sheets are often made of the further strengthened or treated glass, such as tempered glass (also referred to as toughened glass), heat-strengthened glass, or chemically strengthened glass, which are made by further subjecting the un-treated float glass to a thermal tempering treatment, a heat treatment, or certain chemical treatment, respectively. There are, however, a number of drawbacks associated with using such further strengthened glass. For one, as the further treatments give these glass sheets more strength compared to that of the un-treated float glass, they also introduce distortion to the glass surfaces and therefore make them less desirable to be used in laminates. The difficulty (and associated cost) of module fabrication increases with increased glass distortion. Moreover, such further treated float glass is more expensive than the un-treated float glass to produce and therefore increases the overall cost of module manufacturing. Additionally, tempered glass can break spontaneously as the tensile residual stresses needed to balance the surface compressive stress, can cause defects, such as nickel sulphide impurities, to extend catastrophically. There is a need in the industry to develop a technology where the more costly and less flat further strengthened glass is replaced by the more cost effective and undistorted float glass.

### SUMMARY OF THE INVENTION

Disclosed herein is a solar cell module comprising: (a) solar cell layer that comprises thin film solar cells deposited on a first float glass sheet, which has its side that is opposite from the first float glass sheet laminated to, (b) an encapsulant sheet comprising an ionomer, which is laminated to, (c) a second float glass sheet.

### BRIEF DESCRIPTION OF THE DRAWINGS

Each of FIGS. 1-3 is a cross-sectional view, not-to-scale, of an embodiment of the thin film solar cell modules disclosed herein.

FIG. 4 shows a relative comparison between the strength and deflection of ionomer (E1) and ethylene vinyl acetate (EVA) (CE1), versus poly(vinyl butyral) (PVB) (CE2).

FIG. 5 is a picture showing how the module was input into the FEM module.

FIG. 6 shows the calculated distribution of stress and deflection over the surface of the module

### DETAILED DESCRIPTION OF THE INVENTION

Unless otherwise defined, all technical and scientific terms used herein have the same meaning as commonly understood by one of ordinary skill in the art to which this invention belongs. In case of conflict, the specification, including definitions, will control.

Although methods and materials similar or equivalent to those described herein can be used in the practice or testing of the invention, suitable methods and materials are described herein.

Unless stated otherwise, all percentages, parts, ratios, etc., are by weight.

When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

When the term “about” is used in describing a value or an end-point of a range, the disclosure should be understood to include the specific value or end-point referred to.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or.

The transitional phrase “consisting essentially of” limits the scope of a claim to the specified materials or steps and those that do not materially affect the basic and novel characteristic(s) of the claimed invention.

Where applicants have defined an invention or a portion thereof with an open-ended term such as “comprising,” it should be readily understood that unless otherwise stated the description should be interpreted to also describe such an invention using the term “consisting essentially of”.

Use of “a” or “an” are employed to describe elements and components of the invention. This is merely for convenience and to give a general sense of the invention. This description should be read to include one or at least one and the singular also includes the plural unless it is obvious that it is meant otherwise.

In describing certain polymers it should be understood that sometimes applicants are referring to the polymers by the monomers used to produce them or the amounts of the monomers used to produce the polymers. While such a description may not include the specific nomenclature used to describe the final polymer or may not contain product-by-process terminology, any such reference to monomers and amounts should be interpreted to mean that the polymer comprises those monomers (i.e. copolymerized units of those monomers) or that amount of the monomers, and the corresponding polymers and compositions thereof.

In describing and/or claiming this invention, the term “copolymer” is used to refer to polymers formed by copolymerization of two or more monomers. Such copolymers include dipolymers, terpolymers or higher order copolymers.

The term “acid copolymer” as used herein refers to a polymer comprising copolymerized units of an α-olefin, an α,β-ethylenically unsaturated carboxylic acid, and optionally other suitable comonomer(s) such as, an α,β-ethylenically unsaturated carboxylic acid ester.

The term “ionomer” as used herein refers to a polymer that comprises ionic groups that are metal ion carboxylates, for example, alkali metal carboxylates, alkaline earth carboxylates, transition metal carboxylates and/or mixtures of such carboxylates. Such polymers are generally produced by partially or fully neutralizing the carboxylic acid groups of precursor or parent polymers that are acid copolymers, as defined herein, for example by reaction with a base. An example of an alkali metal ionomer as used herein is a sodium ionomer (or sodium neutralized ionomer), for example a copolymer of ethylene and methacrylic acid wherein all or a portion of the carboxylic acid groups of the copolymerized methacrylic acid units are in the form of sodium carboxylates.

Referring now to FIG. 1, disclosed herein is a thin film solar cell module comprising a solar cell layer (12) that comprises a layer of thin film solar cells (16) deposited directly on a first float glass sheet (14) and wherein the solar cell layer (12), on its side that is opposite from the first float glass sheet (14), is further laminated to an ionomer sheet (18) and further to a second float glass sheet (20). The solar cell layer (12) may have a front sun-facing side (which is also referred to as a front side and, when in actual use conditions, would generally face toward the sun) and a back non-sun-facing side (which is also referred to as a back side and, when in actual use conditions, would generally face away from the sun). In one embodiment (30 in FIG. 2), the solar cell module comprises, in the order of position from the front sun-facing side to the back non-sun-facing side, (a) the solar cell layer (12a) comprising the first float glass sheet (i.e., a superstrate) (14) and the thin film solar cells (16a) deposited thereon, (b) the ionomer sheet (i.e., a back encapsulant layer) (18), and (c) the second float glass sheet (i.e., a back sheet) (20). In another embodiment (40 in FIG. 3), the solar cell module comprises, in the order of position from the front sun-facing side to the back non-sun-facing side, (a) the second float glass sheet (i.e., a front sheet) (20), (b) the ionomer sheet (i.e., a front encapsulant layer) (18), and (c) the solar cell layer (12b) comprising the thin film solar cells (16b) deposited on the first float glass sheet (i.e., a substrate) (14).

The term “solar cell” is meant to include any article which can convert light into electrical energy. The thin film solar cells useful in the modules disclosed here include, but are not limited to, a-Si, μc-Si, CdTe, CIS, CIGS, light absorbing dyes, and organic semiconductors based solar cells, as described above in the background section. As disclosed above, the solar cell layer comprised in the module comprises the thin film solar cells deposited directly on a piece of float glass, which may also be referred to as a substrate or superstrate depends on whether the float glass sheet faces to or away from the sun when in use. In addition, the solar cell layer may further comprise electrical wirings, such as cross ribbons and bus bars. Moreover, in those embodiments, wherein the thin film solar cells are deposited on a float glass superstrate, there may also be one or more holes or voids in the float glass back sheet to collect the electrical wires coming out of the solar cells. In one embodiment, the one or more holes or voids may each have a diameter of about 1 to about 100 mm, or about 10 to about 70 mm, or about 25 to about 50 mm. In a further embodiment, such hole(s) or void(s) may be positioned off-center. That is the hole(s) or void(s) are positioned away from the geometric center of the float glass back sheet. In a yet further embodiment, where the module has a rectangular shape, the hole(s) or void(s) may be positioned off-center and closer to one of the long edges. In a yet further embodiment, where the module has a rectangular shape and supported on four sides, the hole(s) or void(s) may be positioned along the center-line of the long edge and one hole diameter from the panel edge. In a yet further embodiment, where the module is supported on two sides, the hole(s) or void(s) may be positioned along the center line of the supported edge and one hole diameter from the panel edge.

The glass sheets used in the thin film solar cell modules are float glass produced by floating molten glass on a bath of molten tin and then allowing it to cool slowly, without being quenched. Such float glass sheets did not undergo further strengthening treatment as those tempered glass, heat-strengthened glass, or chemically strengthened glass and therefore have substantially flat surfaces. The thickness of the float glass sheets may be in the range of about 2 to about 5 mm, or about 2.5 to about 4 mm, or about 2.5 to about 3 mm.

The ionomer sheets (i.e., the front or back encapsulant sheets) that are laminated between the thin film solar cells and second glass sheets (i.e., the front or back sheets) comprises an ionomer composition. By “laminated”, it is meant that, within a laminated structure, the two layers are bonded either directly (i.e., without any additional material between the two layers) or indirectly (i.e., with additional material, such as interlayer or adhesive materials, between the two layers). In one embodiment, the ionomer sheet is directly bonded, at one side, to the solar cells, and at the other side, to the second float glass sheet.

The ionomer composition used here comprises an ionomer that is an ionic, neutralized derivative of a precursor acid copolymer comprising copolymerized units of an a-olefin having 2 to 10 carbon atoms and about 18 to about 30 wt %, or about 20 to about 25 wt %, or about 21 to about 24 wt %, of copolymerized units of an α,β-ethylenically unsaturated carboxylic acid having 3 to 8 carbons, based on the total weight of the precursor acid copolymer.

Suitable a-olefin comonomers may include, but are not limited to, ethylene, propylene, 1-butene, 1-pentene, 1-hexene, 1-heptene, 3 methyl-1-butene, 4-methyl-1-pentene, and the like and mixtures of two or more thereof. In one embodiment, the α-olefin is ethylene.

Suitable α,β-ethylenically unsaturated carboxylic acid comonomers may include, but are not limited to, acrylic acids, methacrylic acids, itaconic acids, maleic acids, maleic anhydrides, fumaric acids, monomethyl maleic acids, and mixtures of two or more thereof. In one embodiment, the α,β-ethylenically unsaturated carboxylic acid is selected from acrylic acids, methacrylic acids, and mixtures of two or more thereof. In another embodiment, the α,β-ethylenically unsaturated carboxylic acid is methacrylic acid.

The precursor acid copolymers may further comprise copolymerized units of one or more other comonomer(s), such as unsaturated carboxylic acids having 2 to 10, or preferably 3 to 8 carbons, or derivatives thereof. Suitable acid derivatives include acid anhydrides, amides, and esters. Esters are preferred. Specific examples of preferred esters of unsaturated carboxylic acids include, but are not limited to, methyl acrylates, methyl methacrylates, ethyl acrylates, ethyl methacrylates, propyl acrylates, propyl methacrylates, isopropyl acrylates, isopropyl methacrylates, butyl acrylates, butyl methacrylates, isobutyl acrylates, isobutyl methacrylates, tert-butyl acrylates, tert-butyl methacrylates, octyl acrylates, octyl methacrylates, undecyl acrylates, undecyl methacrylates, octadecyl acrylates, octadecyl methacrylates, dodecyl acrylates, dodecyl methacrylates, 2-ethylhexyl acrylates, 2-ethylhexyl methacrylates, isobornyl acrylates, isobornyl methacrylates, lauryl acrylates, lauryl methacrylates, 2-hydroxyethyl acrylates, 2-hydroxyethyl methacrylates, glycidyl acrylates, glycidyl methacrylates, poly(ethylene glycol)acrylates, poly(ethylene glycol)methacrylates, poly(ethylene glycol)methyl ether acrylates, poly(ethylene glycol)methyl ether methacrylates, poly(ethylene glycol)behenyl ether acrylates, poly(ethylene glycol)behenyl ether methacrylates, poly(ethylene glycol) 4-nonylphenyl ether acrylates, poly(ethylene glycol) 4-nonylphenyl ether methacrylates, poly(ethylene glycol)phenyl ether acrylates, poly(ethylene glycol)phenyl ether methacrylates, dimethyl maleates, diethyl maleates, dibutyl maleates, dimethyl fumarates, diethyl fumarates, dibutyl fumarates, dimethyl fumarates, vinyl acetates, vinyl propionates, and mixtures of two or more thereof. In one embodiment, the suitable other comonomers are selected from methyl acrylates, methyl methacrylates, butyl acrylates, butyl methacrylates, glycidyl methacrylates, vinyl acetates, and mixtures of two or more thereof. In another embodiment, however, the precursor acid copolymer does not incorporate other comonomers.

The precursor acid copolymers may be polymerized as described in U.S. Pat. No. 3,404,134; U.S. Pat. No. 5,028,674; U.S. Pat. No. 6,500,888; or U.S. Pat. No. 6,518,365.

To obtain the ionomer useful in the ionomer composition of the ionomer sheets (i.e., the front or back encapsulant sheet), the precursor acid copolymer is partially neutralized by one or more cation-containing bases wherein about 5% to about 90%, or about 10% to about 60%, or about 20% to about 55%, of the hydrogen atoms of carboxylic acid groups of the precursor acid are replaced by other cations. That is, the acid groups are neutralized to a level of about 5% to about 90%, or about 10% to about 60%, or about 20% to about 55%, based on the total carboxylic acid content of the precursor acid copolymers as calculated or measured for the non-neutralized precursor acid copolymers.

Any cation-containing base that is stable under the conditions of polymer processing and solar cell fabrication is suitable for use. In one embodiment, the cations used are metal cations, which may be monovalent, divalent, trivalent, multivalent, or mixtures thereof. Useful monovalent metal cations include but are not limited to cations of sodium, potassium, lithium, silver, mercury, copper, and the like, and mixtures thereof. Useful divalent metal cations include but are not limited to cations of beryllium, magnesium, calcium, strontium, barium, copper, cadmium, mercury, tin, lead, iron, cobalt, nickel, zinc, and the like, and mixtures thereof. Useful trivalent metal cations include but are not limited to cations of aluminum, scandium, iron, yttrium, and the like, and mixtures thereof. Useful multivalent metal cations include but are not limited to cations of titanium, zirconium, hafnium, vanadium, tantalum, tungsten, chromium, cerium, iron, and the like, and mixtures thereof. It is noted that when the metal cation is multivalent, complexing agents such as stearate, oleate, salicylate, and phenolate radicals may be included, as described in U.S. Pat. No. 3,404,134. In further embodiment, the metal cations used are monovalent or divalent metal cations. In a yet further embodiment, the metal cations are selected from sodium, lithium, magnesium, zinc, potassium and mixtures thereof. In a yet further embodiment, the metal cations are selected from cations of sodium, zinc and mixtures thereof. In a yet further embodiment, the metal cation is sodium cation.

To obtain the ionomers useful here, the precursor acid copolymers are neutralized with a cation-containing base so that the carboxylic acid groups in the precursor acid copolymer react to form carboxylate groups. The precursor acid copolymers may be neutralized by any conventional procedure, such as those described in U.S. Pat. Nos. 3,404,134 and 6,518,365.

The precursor acid copolymer may have a melt flow rate (MFR) of about 1 to about 1000 g/10 min, or about 20 to about 900 g/10 min, or about 20 to about 70 g/10 min, or about 70 to about 700 g/10 min, or about 100 to about 500 g/10 min, or about 150 to about 300 g/10 min, as determined in accordance with ASTM method D1238 at 190° C. and 2.16 kg.

The resulting ionomer may have a MFR or 25 g/10 min or less, or about of 20 g/10 min or less, or about 10 g/10 min or less, or about 5 g/10 min or less, or about 0.7 to about 5 g/10 min, as determined in accordance with ASTM method D1238 at 190° C. and 2.16 kg.

The ionomer composition may further contain other additives known within the art. The additives may include, but are not limited to, processing aids, flow enhancing additives, lubricants, pigments, dyes, flame retardants, impact modifiers, nucleating agents, anti-blocking agents such as silica, thermal stabilizers, UV absorbers, UV stabilizers, dispersants, surfactants, chelating agents, coupling agents, reinforcement additives, such as glass fiber, fillers and the like. Generally, additives that may reduce the optical clarity of the composition, such as reinforcement additives and fillers, are reserved for those sheets that are used as the back encapsulants.

Thermal stabilizers can be used and have been widely disclosed within the art. Any known thermal stabilizer may find utility within the invention. Exemplary general classes of thermal stabilizers include, but are not limited to, phenolic antioxidants, alkylated monophenols, alkylthiomethylphenols, hydroquinones, alkylated hydroquinones, tocopherols, hydroxylated thiodiphenyl ethers, alkylidenebisphenols, O-, N- and S-benzyl compounds, hydroxybenzylated malonates, aromatic hydroxybenzyl compounds, triazine compounds, aminic antioxidants, aryl amines, diaryl amines, polyaryl amines, acylaminophenols, oxamides, metal deactivators, phosphites, phosphonites, benzylphosphonates, ascorbic acid (vitamin C), compounds that destroy peroxide, hydroxylamines, nitrones, thiosynergists, benzofuranones, indolinones, and the like and mixtures thereof. The ionomer composition may contain any effective amount of thermal stabilizers. Use of a thermal stabilizer is optional. When thermal stabilizers are used, the ionomer composition may contain at least about 0.05 wt % and up to about 10 wt %, or up to about 5 wt %, or up to about 1 wt %, of thermal stabilizers, based on the total weight of the ionomer composition.

UV absorbers can be used and have also been widely disclosed within the art. Any known UV absorber may find utility within the present invention. Exemplary general classes of UV absorbers include, but are not limited to, benzotriazoles, hydroxybenzophenones, hydroxyphenyl triazines, esters of substituted and unsubstituted benzoic acids, and the like and mixtures thereof. The ionomer composition may contain any effective amount of UV absorbers. Use of a UV absorber is optional. When UV absorbers are utilized, the ionomer composition may contain at least about 0.05 wt % and up to about 10 wt %, or up to about 5 wt %, or up to about 1 wt %, of UV absorbers, based on the total weight of the ionomer composition.

Hindered amine light stabilizers (HALS) can be used and have also been widely disclosed within the art. Generally, hindered amine light stabilizers are disclosed to be secondary, tertiary, acetylated, N hydrocarbyloxy substituted, hydroxy substituted N-hydrocarbyloxy substituted, or other substituted cyclic amines which are characterized by a substantial amount of steric hindrance, generally derived from aliphatic substitution on the carbon atoms adjacent to the amine function. The ionomer composition may contain any effective amount of hindered amine light stabilizers. Use of hindered amine light stabilizers is optional. When hindered amine light stabilizers are used, the ionomer composition may contain at least about 0.05 wt % and up to about 10 wt %, or up to about 5 wt %, or up to about 1 wt %, of hindered amine light stabilizers, based on the total weight of the ionomer composition.

Silane coupling agents may be added to the ionomer composition to improve its adhesive strength. Exemplary silane coupling agents that are useful in the compositions of the invention include, but are not limited to, γ-chloropropylmethoxysilane, vinyltrimethoxysilane, vinyltriethoxysilane, vinyltris(β-methoxyethoxy)silane,γ-vinylbenzylpropyltrimethoxysilane, N-β-(N-vinylbenzylaminoethyl)-γ-aminopropyltrimethoxysilane, γ-methacryloxypropyltrimethoxysilane, vinyltriacetoxysilane, γ-glycidoxypropyltrimethoxysilane, γ-glycidoxypropyltriethoxysilane, β-(3,4-epoxycyclohexyl)ethyltrimethoxysilane, vinyltrichlorosilane, γ-mercaptopropylmethoxysilane, γ-aminopropyltriethoxysilane, N-n-(aminoethyl)-γ-aminopropyltrimethoxysilane, and mixtures of two or more thereof. The silane coupling agents may be incorporated in the ionomer composition at a level of about 0.01 to about 5 wt %, or about 0.05 to about 1 wt %, based on the total weight of the ionomer composition.

Further, the ionomer sheet may have total thickness of about 1 to about 120 mils (about 0.025 to about 3 mm), or about 5 to about 100 mils (about 0.127 to about 2.54 mm), or about 5 to about 45 mils (about 0.127 to about 1.14 mm), or about 10 to about 35 mils (about 0.25 to about 0.89 mm), or about 10 to about 30 mils (about 0.25 to about 0.76 mm). Yet further, when the ionomer sheet is comprised in the thin film module as the front encapsulant layer, it needs to be sufficiently transparent. For example, the ionomer sheet may have a haze level of less than about 2%, as determined in accordance with ASTM D1003.

The ionomer sheet may have a smooth or rough surface on one or both sides. In one embodiment, the sheet has rough surfaces on both sides to facilitate de-airing during the lamination process. Rough surfaces can be created by mechanically embossing or by melt fracture during extrusion of the sheets followed by quenching so that surface roughness is retained during handling. The surface pattern can be applied to the sheet through common art processes. For example, the as-extruded sheet may be passed over a specially prepared surface of a die roll positioned in close proximity to the exit of the die which imparts the desired surface characteristics to one side of the molten polymer. Thus, when the surface of such a die roll has minute peaks and valleys, the polymer sheet cast thereon will have a rough surface on the side that is in contact with the roll, and the rough surface generally conforms respectively to the valleys and peaks of the roll surface. Such die rolls are disclosed in, e.g., U.S. Pat. No. 4,035,549 and U.S. Patent Publication No. 20030124296.

The ionomer sheets can be produced by any suitable process. For example, the sheets may be formed through dipcoating, solution casting, compression molding, injection molding, lamination, melt extrusion casting, blown film, extrusion coating, tandem extrusion coating, or by any other procedures that are known to those of skill in the art. In certain embodiments, the sheets are formed by melt extrusion casting, melt coextrusion casting, melt extrusion coating, or tandem melt extrusion coating processes.

As demonstrated by the examples provided herebelow, when an ionomer, instead of other polymers such as ethylene vinyl acetate (EVA) or poly(vinyl butyral) (PVB), is used as the encapsulant material, it improves the module's overall stress resistance and reduces the module's deflection under pressure, and therefore makes it feasible to obtain a mechanically reliable thin film module without the use of the more expensive and less flat further strengthened glass.

The thin film solar cell modules disclosed here may further comprise other functional film or sheet layers (e.g., dielectric layers or barrier layers) embedded within the module. Such functional layers may be derived from any of suitable polymeric films or those that are coated with additional functional coatings. For example, poly(ethylene terephthalate) films coated with a metal oxide coating, such as those disclosed within U.S. Pat. Nos. 6,521,825 and 6,818,819 and European Patent No. EP1182710, may function as oxygen and moisture barrier layers in the laminates.

If desired, a layer of nonwoven glass fiber (scrim) may also be included between the solar cell layers and the encapsulant sheets to facilitate de-airing during the lamination process and/or to serve as reinforcement for the encapsulants. The use of such scrim layers is disclosed within, e.g., U.S. Pat. Nos. 5,583,057; 6,075,202; 6,204,443; 6,320,115; and 6,323,416 and European Patent No. EP0769818.

If desired, one or both surfaces of the glass protective sheets or the ionomer encapsulant sheets incorporated within the thin film solar cell module may be treated prior to the lamination process to enhance the adhesion to other laminate layers. This adhesion enhancing treatment may take any form known within the art and includes flame treatments (see, e.g., U.S. Pat. Nos. 2,632,921; 2,648,097; 2,683,894; and 2,704,382), plasma treatments (see e.g., U.S. Pat. No. 4,732,814), electron beam treatments, oxidation treatments, corona discharge treatments, chemical treatments, chromic acid treatments, hot air treatments, ozone treatments, ultraviolet light treatments, sand blast treatments, solvent treatments, and combinations of two or more thereof. Also, the adhesion strength may be further improved by further applying an adhesive or primer coating on the surface of the laminate layer(s). For example, U.S. Pat. No. 4,865,711 discloses a film or sheet with improved bondability, which has a thin layer of carbon deposited on one or both surfaces. Other exemplary adhesives or primers may include silanes, poly(allyl amine) based primers (see e.g., U.S. Pat. Nos. 5,411,845; 5,770,312; 5,690,994; and 5,698,329), and acrylic based primers (see e.g., U.S. Pat. No. 5,415,942). The adhesive or primer coating may take the form of a monolayer of the adhesive or primer and have a thickness of about 0.0004 to about 1 mil (about 0.00001 to about 0.03 mm), or preferably, about 0.004 to about 0.5 mil (about 0.0001 to about 0.013 mm), or more preferably, about 0.004 to about 0.1 mil (about 0.0001 to about 0.003 mm).

A series of the thin film solar cell modules described above may be further linked to form a solar cell array, which can produce a desired voltage and current.

Any lamination process known within the art (such as an autoclave or a non-autoclave process) may be used to prepare the thin film solar cell modules.

In an exemplary process, the component layers of the thin film solar cell module are stacked in the desired order to form a pre-lamination assembly. The assembly is then placed into a bag capable of sustaining a vacuum (“a vacuum bag”), the air is drawn out of the bag by a vacuum line or other means, the bag is sealed while the vacuum is maintained (e.g., at least about 27-28 in Hg (689-711 mm Hg)), and the sealed bag is placed in an autoclave and the pressure is raised to about 150 to about 250 psi (about 11.3 to about 18.8 bar), a temperature of about 130° C. to about 180° C., or about 130° C. to about 160° C., or about 135° C. to about 155° C., or about 145° C. to about 155° C., for about 10 to about 50 min, or about 20 to about 45 min, or about 20 to about 40 min, or about 25 to about 35 min. A vacuum ring may be substituted for the vacuum bag. One type of suitable vacuum bag is disclosed within U.S. Pat. No. 3,311,517. Following the heat and pressure cycle, the air in the autoclave is cooled without adding additional gas to maintain pressure in the autoclave. After about 20 min of cooling, the excess air pressure is vented and the laminates are removed from the autoclave.

Alternatively, the pre-lamination assembly may be heated in an oven at about 80° C. to about 120° C., or about 90° C. to about 100° C., for about 20 to about 40 min, and thereafter, the heated assembly is passed through a set of nip rolls so that the air in the void spaces between the individual layers may be squeezed out, and the edge of the assembly sealed. The assembly at this stage is referred to as a pre-press.

The pre-press may then be placed in an air autoclave where the temperature is raised to about 120° C. to about 160° C., or about 135° C. to about 160° C., at a pressure of about 100 to about 300 psi (about 6.9 to about 20.7 bar), or preferably about 200 psi (13.8 bar). These conditions are maintained for about 15 to about 60 min, or about 20 to about 50 min, after which the air is cooled while no further air is introduced to the autoclave. After about 20 to about 40 min of cooling, the excess air pressure is vented and the laminated products are removed from the autoclave.

The thin film solar cell modules may also be produced through non-autoclave processes. Such non-autoclave processes are disclosed, e.g., in U.S. Pat. Nos. 3,234,062; 3,852,136; 4,341,576; 4,385,951; 4,398,979; 5,536,347; 5,853,516; 6,342,116; and 5,415,909, U.S. Patent Publication No. 20040182493, European Patent No. EP1235683 B1, and PCT Patent Publication Nos. WO9101880 and WO03057478. Generally, the non-autoclave processes include heating the pre-lamination assembly and the application of vacuum, pressure or both. For example, the assembly may be successively passed through heating ovens and nip rolls. Or the non-autoclave lamination process may include the steps of positioning all the component layers of the laminated structure to form a pre-lamination assembly and subjecting the assembly to heat, vacuum, and optionally pressure. See e.g., U.S. Pat. Nos. 3,234,062; 4,421,589; 5,238,519; 5,536,347; 5,759,698; 5,593,532; 5,993,582; 6,007,650; 6,134,784; 6,149,757; 6,241,839; 6,367,530; 6,369,316; 6,481,482; U.S. Patent Publication Nos. 20040182493; 20070215287, and PCT Patent Publication No. WO 2006057771. Various types of laminators, such as the Meier ICOLAM® 10/08 laminator (Meier Vakuumtechnik GmbH, Bocholt, Germany), SPI-Laminators with model numbers 1834N, 1734N, 680N, 580 N, 580, and 480 (Spire Corporation, Bedford, Mass.), Module Laminators LM, LM-A and LM-SA series (NPC Incorporated, Tokyo, Japan), are commercially available and can be useful.

These examples of lamination processes are not intended to be limiting. Essentially any lamination process may be used.

If desired, the edges of the solar cell module may be sealed to reduce moisture and air intrusion and potential degradative effects on the efficiency and lifetime of the solar cell(s) by any means disclosed within the art. Suitable edge seal materials include, but are not limited to, butyl rubber, polysulfide, silicone, polyurethane, polypropylene elastomers, polystyrene elastomers, block elastomers, styrene-ethylene-butylene-styrene (SEBS), and the like.

The invention is further illustrated by the following examples of certain embodiments.

### Examples

### Comparative Examples CE1-CE2 and Examples E1

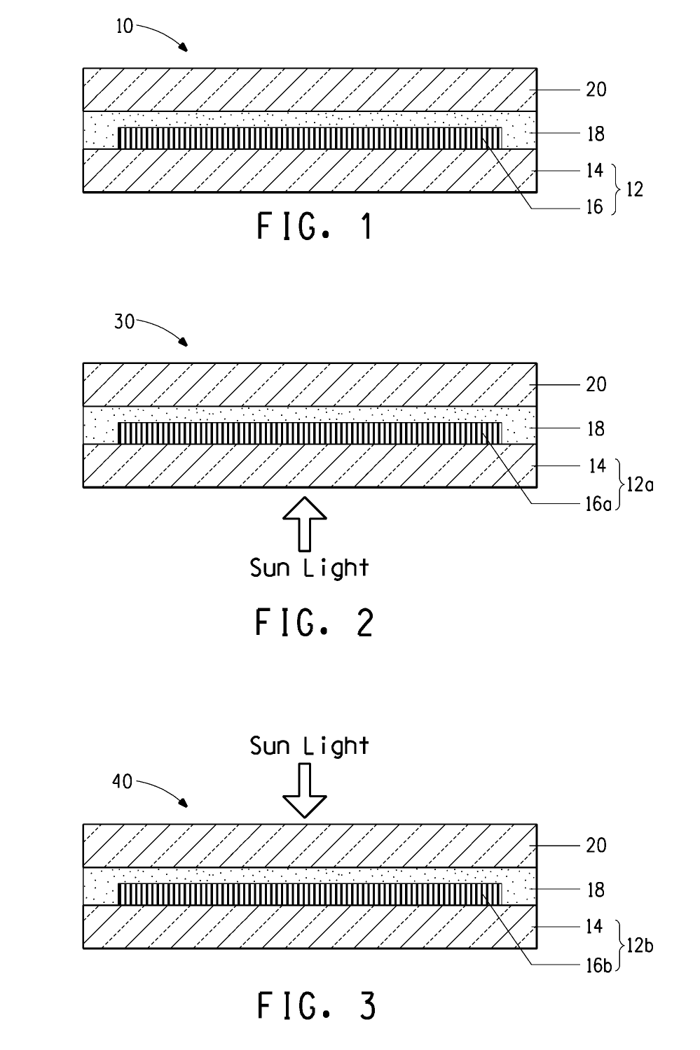

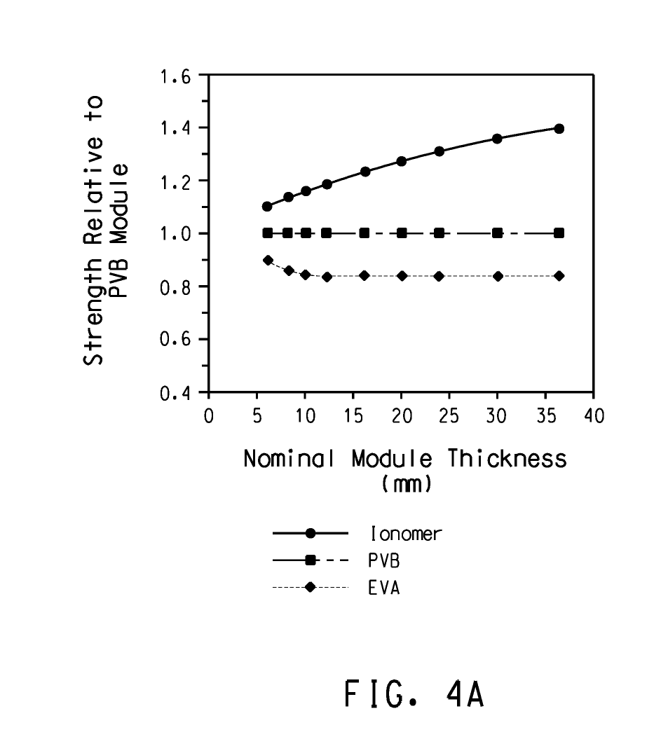

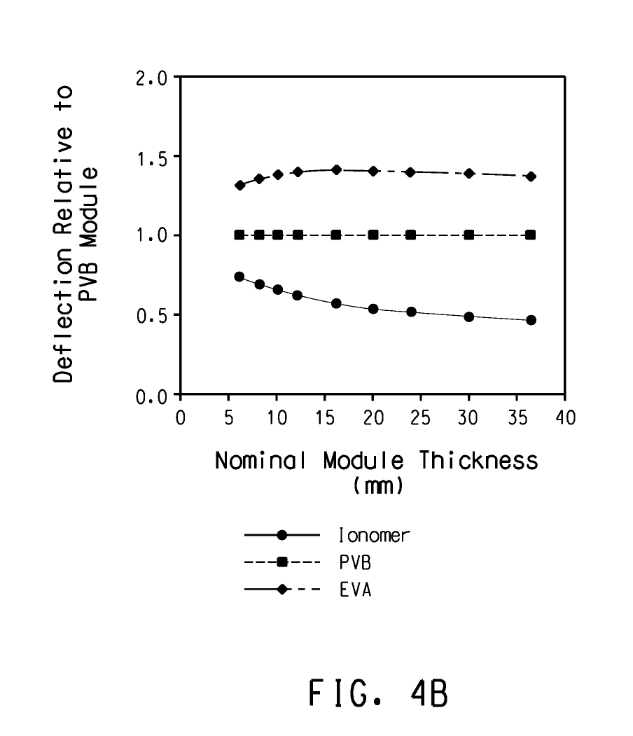

FIG. 4 shows a relative comparison between the calculated strength and calculated deflection of modules fabricated with ionomer (E1) and EVA (CE1), versus PVB (CE2). These properties were calculated using established engineering formulae for two-side simply-supported beams in conjunction with ASTM El 300-09 (Appendix X 11) for computation of the laminate effective thickness. The module structure comprised of a 1.52 mm encapsulant in combination with various glass thickness. The unsupported module span was 2 m. The property values used to model the encapsulant were: 1) EVA, Young's Modulus=1.23 MPa; 2) PVB, Young's Modulus=2.94 MPa; and c) ionomer, Young's Modulus=213 MPa. The calculations demonstrate that ionomer encapsulant has better strength compared to the other two encapsulants across the range of laminate thicknesses, thus gives the modules more mechanical strength.

### Comparative Examples CE3-CE4 and Example E2

Finite element modeling (FEM) was used to calculate the stress development and deflection in the fictitious thin film modules in these examples. In each example, a three-layer laminate consisting of two outer glass plates and a polymer interlayer was analyzed. The laminate was modeled using three-dimensional finite elements. Glass plates were discretized using 8-node brick elements with incompatible modes to allow accurate capture of bending deformation. Elements that were used to model the polymer interlayer used a hybrid formulation that yielded accurate results for near-incompressible materials. Typical loading histories were either an applied pressure ramped to its maximum value over a specified time period, or applied rapidly and then held constant for the same duration. The model was developed on and solved using the commercial finite element program ABAQUS™. Sufficiency of the discretization was established by generating models with successively finer meshes until mesh-independent results were obtained, as judged by convergence of the computed maximum principal stress and deflection at the maximum pressure applied in the simulation. Soda-lime silica float glass was modeled as a linear-elastic material with a Young's modulus of 72 GPa and Poisson ratio of 0.22. It was shown that for the range of rates and deformation encountered in laminate deformation to generate glass breakage, interlayers could be represented accurately by linear viscoelastic constitutive equations. These equations were developed independently for the polymers studied here from dynamic mechanical analysis data obtained following ASTM D 4065. The forced constant amplitude, fixed frequency tension oscillation test specified in Practice D 4065 was used and the shear modulus master curves extracted for the temperatures and load durations of interest.

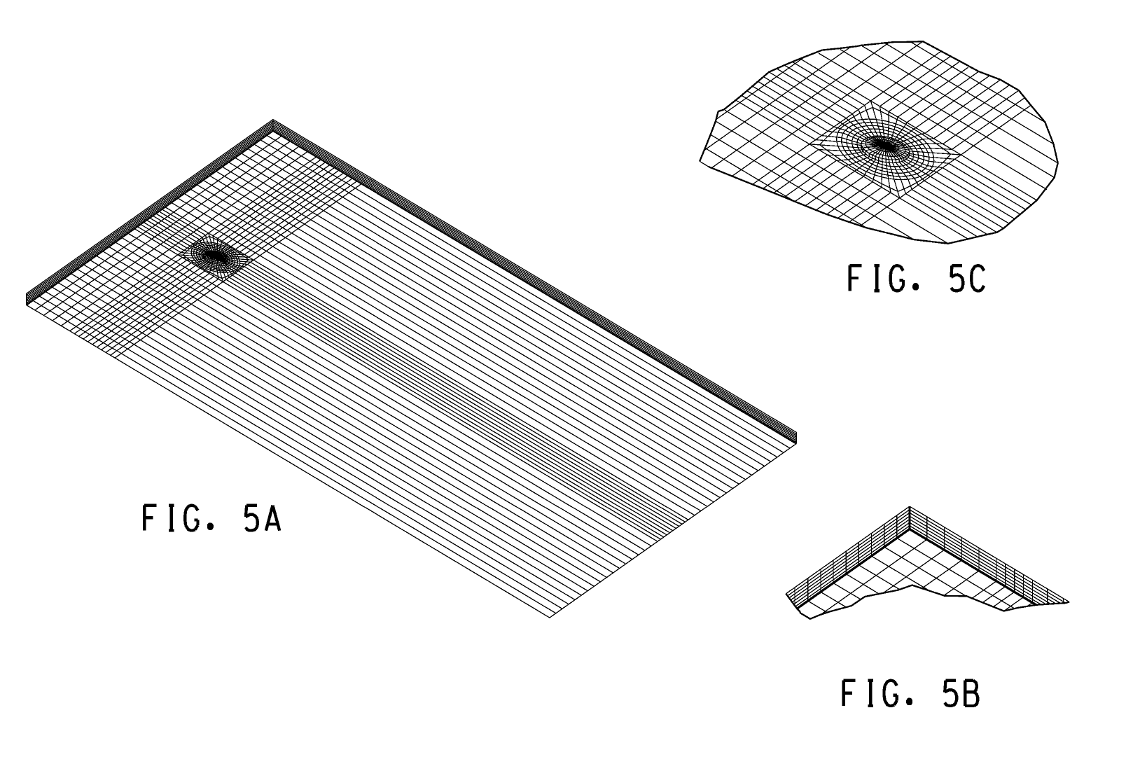

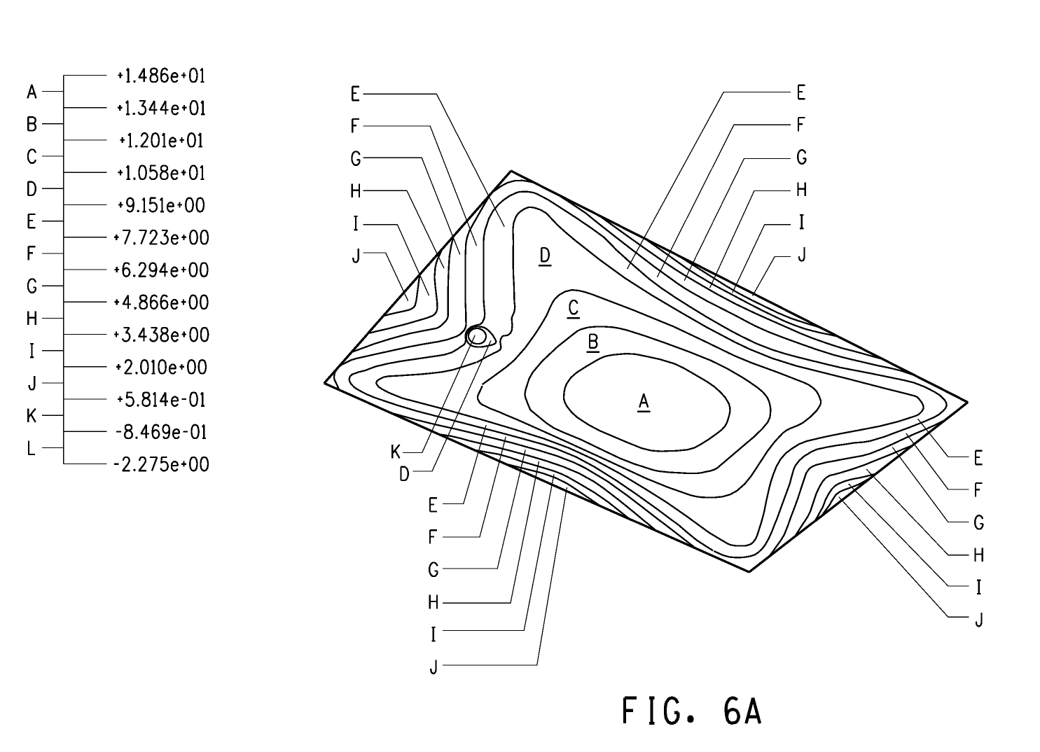

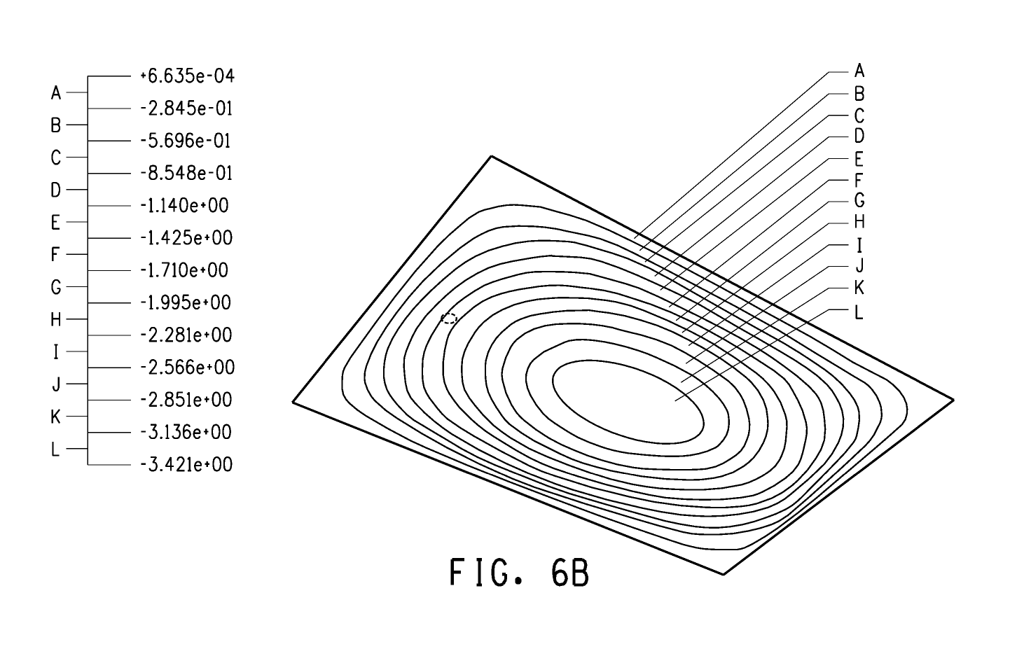

The fictitious thin film modules had a dimension of 1200×800 mm and comprised a 0.89 mm thick polymeric interlayer laminated between two 3 mm thick heat-strengthened glass sheets. In addition, one of the two glass sheets had an off-center hole with a diameter of 40 mm positioned at 160 mm normally from the short edge along its center-line, which resembled the hole that would be used in real modules for collecting the electrical wires and connections. In each of CE3-CE4 and E2, the interlayer was formed of EVA, PVB, and ionomer, respectively. The property values used to model the encapsulant were: 1) EVA, Young's Modulus=5.0 MPa, Poisson ratio=0.4999; 2) PVB, Young's Modulus=1.5 MPa, Poisson ratio=0.4999; and c) ionomer, Young's Modulus=416 MPa, Poisson ratio=0.465. Using the ABAQUS (v6.7) software, the maximum stress development and deflection of each of the laminates on either 4-side support or 2-side (long edges of the module) support was calculated and reported in Table 1. FIG. 5 is a picture showing how the module was input into the FEM module and FIG. 6 shows the calculated distribution of stress and deflection over the surface of the module.

The results demonstrate that when ionomer was used as the interlayer material in E2, the laminates had the least glass stress development and the least deflection for a given support. The difference became even larger when the laminates are 2-side supported. Thus, a thin film module with sufficient mechanical reliability can be obtained when ionomer is used as the encapsulant material and untreated float glass are used as the two protective layers. Also demonstrated by the results is that when the laminates are 4-side supported and when then interlayer layer material is ionomer or EVA, the maximum glass stress location is in the center even when the hole on the back sheet is off-centered. In contrast, also under 4-side support, when the interlayer material is PVB, the maximum glass stress location is around the hole position. Therefore, positioning the hole on the back sheet off center can further improve the mechanical reliability of a thin film module having an ionomer encapsulant sheet.

TABLE 1

| | | | |
|---|---|---|---|
| | Maximal | Maximum Glass | Maximum |
| | Pressure and | Stress and | Deflection |
| Encapsulant | Support (kPa) | Location (MPa) | (mm) |

| | | | | |
|---|---|---|---|---|
| PV5300 | 2.4 (4-sides) | 14.9 | (center) | 3.42 |
| EVA | 2.4 (4-sides) | 17.7 | (center) | 5.98 |
| PV5200 | 2.4 (4-sides) | 21.3 | (hole) | 7.81 |
| PV5300 | 2.4 (2-sides) | 45.4 | (hole) | 6.35 |
| EVA | 2.4 (2-sides) | 53.3 | (hole) | 10.3 |
| PV5200 | 2.4 (2-sides) | 59.5 | (hole) | 16.1 |

What is claimed is:

1. A solar cell module comprising
(a) solar cell layer that comprises thin film solar cells deposited on a first float glass sheet, which has its side that is opposite from the first float glass sheet laminated to,
(b) an encapsulant sheet comprising an ionomer, which is laminated to,
(c) a second float glass sheet.

2. The solar cell module of claim 1, wherein the thin film solar cells are selected from the group consisting of amorphous silicon (a-Si), microcrystalline silicon (μc-Si), cadmium telluride (CdTe), copper indium selenide (CIS), copper indium/gallium diselenide (GIGS), light absorbing dyes, and organic semiconductors based thin film solar cells.

3. The solar cell module of claim 1, wherein the each of the first and second float glass sheets independently has a thickness of about 2 to about 5 mm.

4. The solar cell module of claim 1, wherein the ionomer comprises carboxylate groups and cations and is the product of a neutralization of a precursor α-olefin carboxylic acid copolymer; the precursor α-olefin carboxylic acid copolymer comprises (i) copolymerized units of an α-olefin having 2 to 10 carbons and (ii) about 18 to about 30 wt % of copolymerized units of an α,β-ethylenically unsaturated carboxylic acid having 3 to 8 carbons, based on the total weight of the α-olefin carboxylic acid copolymer; and about 5% to about 90% of the total content of the carboxylic acid groups present in the precursor α-olefin carboxylic acid copolymer are neutralized to form the ionomer.

5. The solar cell module of claim 1, wherein the ionomer encapsulant sheet has a thickness of about 1 to about 120 mils (about 0.025 to about 3 mm).

6. The solar cell module of claim 1, wherein the ionomer encapsulant sheet has thickness of about 5 to about 45 mils (about 0.127 to about 1.14 mm).

7. The solar cell module of claim 1, wherein, when in use, the first float glass sheet faces to the sun and serves as a superstrate for the solar cells and the second float glass faces away from the sun and serves as a back sheet.

8. The solar cell module of claim 7, wherein the solar cell layer further comprises electrical wires coming out of the module through a hole positioned on the float glass back sheet.

9. The solar cell module of claim 8, wherein the hole has a diameter of about 10 to about 100 mm.

10. The solar cell module of claim 8, wherein the hole is positioned off-center.

11. The solar cell module of claim 1, wherein, when in use, the first float glass sheet faces away from the sun and serves as a substrate for the solar cells and the second float glass faces to the sun and serves as a front sheet.

12. The solar cell module of claim 11, wherein the ionomer comprising encapsulant sheet is sufficiently transparent.

13. A process for preparing a solar cell module, comprising: (i) providing an assembly comprising all the component layers recited in claim 1 and (ii) laminating the assembly to form the solar cell module.

14. The process of claim 13, wherein the laminating step is conducted by subjecting the assembly to heat and optionally vacuum or pressure.
